(19) United States
(12) Patent Application Publication
(10) Pub. No.: US 2026/0311203 A1
(43) Pub. Date: Oct. 8, 2026

(54) System and Method for the Generation of an Interactive Cost Estimate

(71) Applicant: Solva Group Ltd, Cardiff (GB)

(72) Inventors: Liam Shields, Swansea (GB); Oliver Marsh, Barry (GB)

(73) Assignee: Solva Group Ltd, Cardiff (GB)

(21) Appl. No.: 19/639,113

(22) Filed: Apr. 3, 2026

(30) Foreign Application Priority Data
Apr. 3, 2025 (GB) 2505046.9

(51) Int. Cl. G06Q 30/0201

(52) U.S. Cl. CPC G06Q 30/0206

(57) ABSTRACT

The present invention relates to a system for the preparation of interactive Bill of Quantities (BoQ) data and/or interactive cost estimate data and a method of generation of the foregoing wherein the system is integrated into or in communication with modelling software and the resultant real-time generated BoQ data and/or cost estimate data is saved within a modelling file of the modelling software.

The present invention relates to a system and method for the generation of an interactive Bill of Quantities (BoQ) data and interactive cost estimate data from a computer modelling file, and particularly systems and methods for the generation of such interactive BoQ and cost estimate data from a computer modelling file in real time and the provision of such B0Q and cost estimate software to said computer modelling file for saving therein.

### BACKGROUND OF THE INVENTION

In the construction industry, it is necessary to estimate the costs of the construction project prior to obtaining budgetary approval and confirmed instructions that work can commence. The preparation of such cost estimates is extremely complex and time consuming, and it is important that the cost estimate is as accurate as possible to ensure that the project can be delivered with budget and within a defined time period.

There are many software packages that are used to generate 2D and 3D design models for use in the construction industry. For example, AutoCAD is a 2D and 3D computer-aided design (CAD) software application. Typically, AutoCAD is used to create detailed engineering drawings, that will be used on a construction project, these detailed drawings show all the various components required for the project, for example, highway arrangements, pavements, drainage and ducting arrangements, earthwork requirements, landscaping, steel work requirements, etc. Once the AutoCAD .dwg file has been finalised for the purposes of the quote, a user will need to individually select each component from the opened .dwg file and manually measure the distances involved to assess the amount of each component that is required. Once the quantity of a component has been determined from the AutoCAD .dwg file, a rate per quantity will need to be identified, and the resultant quantity and cost information inserted into a spreadsheet. The process then continues with the next component in the AutoCAD .dwg file. This process is laborious and time-consuming, and therefore cost-intensive. Further, any errors in accuracy can significantly affect the final cost estimate.

Further complexity arises due to the large number of materials, estimated amounts of materials required to complete the project and associated labour costs, geographical location and associated material and supply costs, permit costs, legal fees, and so on.

A further issue is the necessity to revise the cost estimate based on decisions made both prior to the project commencing and during the undertaking of the work, which may alter the project parameters and associated labour and material costs, which in turn may be influenced by inflation, supply issues, changing legal requirements etc.

For all the above reasons, the preparation and revision of cost estimates can be laborious and extremely time consuming. Further, the inevitable influence of human error will have a potentially significant influence on cost estimate accuracy.

Often, to resolve any potential cost estimate inaccuracies, site visits are required to establish more accurate data on which to base the cost estimate. Such site visits are time-consuming and may incur significant travel miles, thereby increasing the travel costs and associated carbon footprint. For example, the cost estimate may be prepared several hundred miles from the site at which the project will be subsequently undertaken. It is to be appreciated that such site visits are inconvenient, and where multiple site visits are required for a complex project, impact on man-hours, labour and transport costs and carbon footprint can be significant.

There is therefore a need for an improved system and method of preparation and/or revision of Bill of Quantities (BoQ) and cost estimates which addresses the deficiencies of the prior art. The present invention seeks to address the problems of the prior art.

### SUMMARY OF THE INVENTION

Aspects of the present invention are set out in the attached claims.

A first aspect of the present invention provides a system for generating interactive Bill of Quantities (BoQ) data for use in the preparation of interactive cost estimate software, the system comprising:
(i) a controller; and
(ii) a user interface in communication with the controller,
wherein, on generation of item-specific description and quantity data from a computer aided design file, the system is configured to read and extract the item-specific description and quantity data from the computer modelling file; and
wherein the controller is further operable to
(a) generate BoQ data in dependence upon the extracted item-specific description and quantity data; and
(b) supply the BoQ data to the computer modelling file.

A Bill of Quantities (BoQ) is a structured set of data that itemises materials, labour and services required for a project, such as construction project, allowing contractors to quantify the type and number of items in a project. This may be subsequently used to generate a cost estimate for the project.

The expression ‘computer modelling file’ is intended to mean any computer-generated design file holding data relating to a 2D or 3D design. An example of such a file is a computer aided design file (CAD) such as Auto CAD data received from a CAD .dwg file. However, it is to be appreciated that the CAD data may be received from any other suitable, compatible file format, generated by any suitable modelling software such as, but not limited to, Autodesk Civil 3D, AutoCAD, Revit, VectorWorks and Autodesk software packages.

The BoQ data is then held within the computer modelling file such that the BoQ data is readily accessible to any authorised person accessing the file.

In one embodiment, the system further comprises: a rate database in communication with the controller and populated with item-specific rate data,
wherein, the controller is further operable to: identify the item-specific rate data corresponding to the extracted item-specific description and quantity data from each respective data layer; generate cost estimate data in dependence upon the extracted item-specific description and quantity data and the corresponding item-specific rate data; and supply the cost estimate data to the computer modelling file.

The item-specific rate data allows a cost estimate to be generated based on the extracted item-specific description and quantity data, which is provided to the computer modelling file to provide a cumulative cost estimate for the design project.

Preferably, the controller is configured to supply the cost estimate data to the computer modelling file in real time. Thus, as a user updates the computer modelling file with additional item-specific description and quantity data, the system will update the cost estimate held on the computer modelling file to reflect the change in items present in the design held on the computer modelling file.

In one embodiment, on revision of the item-specific description and quantity data in the computer modelling file, the controller is further configured to:
(i) extract the revised item-specific description and quantity data from the computer modelling file, generate revised BoQ data in dependence upon the extracted revised item-specific description and quantity data; and
(ii) replace the BoQ data in the computer modelling file with the revised BoQ data.

Thus, as the computer modelling file is updated, the BoQ generated by the system is revised to accommodate the updates. In other words, if a change is made to the item-specific quantity, the system will detect the change, and generate a revised BoQ in dependence upon the item-specific description and the change in the item-specific quantity and generate a revised BoQ to reflect the changes.

Preferably, the controller is further configured to generate revised cost estimate data in dependence upon the extracted revised item-specific description and quantity data and the corresponding item-specific rate data; and
replace the cost estimate data in the computer modelling file with the revised cost estimate data.

The use of the revised BoQ together with the item-specific rate data allows revised cost estimate data to be generated and supplied to the computer modelling file.

In one embodiment, the computer modelling file is generated from modelling software selected from the group comprising: Autodesk Civil 3D, AutoCAD, Revit, VectorWorks and Autodesk software packages. However, it is to be appreciated that any other modelling software may be use as an alternative to, or in addition to, any of the aforementioned modelling software.

The controller may be further configured to receive project-specific data from the user interface and populate the modelling file with the project-specific data. For example, a user may input additional details, such as project, title, location etc, and this data may be provided to, and savid in, the computer modelling file, in addition to the BoQ data and cost estimate data.

The controller may be further configured to adjust the item-specific rate data in dependence upon one or more predetermined factors prior to generation of the cost estimate in dependence upon the item-specific description and quantity data and the item-specific rate data.

Preferably, the factors are selected from the group comprising one or more of cost data, location data, and inflation data. However, it is to be appreciated that the factors may include any other appropriate quantifiable factors that are relevant to the item-specific rate data and may require adjustment over time.

The item-specific rate data may be selectively adjusted in dependence upon user-generated input received by the controller from the user interface. This allows manual control over item-specific rate data by a user, where appropriate.

The BoQ and/or cost estimate may be selectively adjusted in dependence upon subsequent user generated input received by the controller from the user interface.

A second aspect of the present invention provides a method of generation of interactive Bill of Quantity (BoQ) data, the method comprising the steps of:
a. providing a system as claimed in any preceding claim, wherein the system is integrated into or in communication with, modelling software;
b. generating a modelling file within the modelling software or providing a modelling file to the modelling software;
c. extracting item-specific description and quantity data from respective layers of the modelling file;
d. generating BoQ data in dependence upon the item-specific description and quantity data;
e. providing the BoQ data to the modelling file; and
f. saving the BoQ data in the modelling file.

In one embodiment, the method may further comprising the steps of generating cost estimate data in dependence upon the item-specific description and quality data and the item specific fate data; providing the cost estimate data to the modelling file; and saving the cost estimate data in the modelling file.

In a further embodiment, the method further comprises the step of adjusting the item-specific rate data in dependence upon one or more predetermined factors selected from the group comprising one or more of cost data, location data, and inflation data.

In a further embodiment, the method may further comprise the step of adjusting the item-specific rate data in dependence upon user-generated input received by the controller from the user interface.

The method may further comprise the step of adjusting the cost estimate in dependence upon subsequent user-generated input received by the controller from the user interface.

Preferably, adjusted cost estimate data changes as a consequence of adjustments to the item-specific rate data are provided to the modelling file to replace corresponding previously provided cost-estimate data.

Preferably, the adjusted cost estimate data is saved to the modelling file.

A third aspect of the present invention provides a system for preparing an interactive cost estimate, the system comprising:
a. a controller
b. a rate database in communication with the controller and populated with item-specific rate data;
c. a results database configured to receive information from the controller; and
d. a user interface in communication with the controller,
wherein the controller is operable to receive item-specific description and quantity data from a computer modelling file comprising a plurality of data layers, wherein each data layer comprises item-specific description and quantity data, and wherein the controller is operable to read and extract the item-specific description and quantity data from each respective data layer; and
wherein the controller is further operable to identify the item-specific rate data corresponding to the extracted item-specific description and quantity data from each respective data layer and to populate the results database with the extracted item-specific description and quantity data and corresponding item-specific rate data extracted from each respective data layer and to generate a cost estimate in dependence upon the item-specific description and quantity data and the item-specific rate data.

Preferably, the data is Auto CAD data received from a CAD .dwg file. However, it is to be appreciated that the CAD data may be received from any other suitable, compatible file format, generated by any suitable computer modelling software, such as, but not restricted to Autodesk Civil 3D, AutoCAD, Revit, VectorWorks and Autodesk software packages.

In one embodiment, the controller is operable to transmit the cost estimate to the user interface for viewing by a user.

Thus, in contrast to the previous aspects of the present invention, in this aspect, the computer modelling file may be uploaded to the system, the cost estimate generated by the system and then transmitted to the user interface for viewing by a user.

In a further embodiment, the controller is further configured to receive project-specific data from the user interface and populate the results database and/or cost estimate with the project-specific data.

In a further embodiment, the controller is further operable to adjust the item-specific rate data in dependence upon one or more predetermined factors prior to generation of the cost estimate in dependence upon the item-specific description and quantity data and the item-specific rate data.

The predetermined factors may include, but are not limited to, one or more of cost data, location data, and inflation data.

The item-specific rate data may be selectively adjusted in dependence upon user-generated input received by the controller from the user interface.

The cost estimate may be selectively adjusted in dependence upon subsequent user generated input received by the controller from the user interface.

A further embodiment of the present invention provides a method of generation of an interactive cost estimate, the method comprising the steps of:
a. providing a system as claimed in any preceding claim;
b. providing a computer modelling file to the controller via the user interface;
c. extracting item-specific description and quantity data from respective layers of the computer modelling file; and
d. generating of a cost estimate in dependence upon the item-specific description and quantity data and the item-specific rate data.

The method of generation of an interactive cost estimate may further comprise the step of transmitting the cost estimate to the user interface.

The method of generation of an interactive cost estimate may further comprise the step of receiving project-specific data from the user interface and populating the results database and/or cost estimate with the project-specific data.

The method of generation of an interactive cost may further comprise the step of adjusting the item-specific rate data in dependence upon one or more predetermined factors selected from the group comprising one or more of cost data, location data, and inflation data.

The method of generation of an interactive cost estimate may further comprise the step of adjusting the item-specific rate data in dependence upon user-generated input received by the controller from the user interface.

The method of generation of an interactive cost estimate may further comprise the step of adjusting the cost estimate in dependence upon subsequent user-generated input received by the controller from the user interface.

### BRIEF DESCRIPTION OF THE DRAWINGS

Embodiments of the invention will now be described with reference to the following figures, in which:

FIG. 1 is an illustration of a first embodiment of a system in accordance with the present invention;

FIG. 2 is a flow chart showing the steps involved in the preparation of a cost estimate in accordance with a first embodiment of the present invention; and

FIG. 3 is a flow chart showing the steps involve in the preparation of cost estimate data in accordance with a second embodiment of the present invention.

### DETAILED DESCRIPTION OF THE PREFERRED EMBODIMENTS

There are many different types of modelling software used by architects, civil engineers, designers and contractors to generate 2D and 3D models. For example, Autodesk Civil 3D is a 3D building information modelling (BIM) software tailored to enable professionals to create dynamic and data-rich models for infrastructure projects, including roads, land development and utilities. AutoCAD is a computer aided design (CAD) software used to create precise 2D and 3D technical drawings and models. Revit is a powerful, intelligent 3D BIM software used to design, document, visualise and simulate buildings. VectorWorks is also a 3D design software, and Autodesk provide a large number of software products for managing projects across the architectural, engineering, construction, and manufacturing industries. It is to be appreciated that the system of the present invention is intended to interact with, or be integrated into, any of the aforementioned modelling software. It is also to be appreciated that the modelling software options include, but are not limited to, Autodesk Civil 3D, AutoCAD, Revit, VectorWorks and Autodesk software packages, and that the system of the present invention may interact with, or be integrated into, any other suitable modelling software that is suitable for the generation of dynamic 2D and 3D models.

It is to be understood that a Bill of Quantities (BoQ) is a structured set of data, often provided in the form of a digital document, that itemises materials, labour and services required for a project (such as a construction project), allowing contractors to price specific quantities. For example, the BoQ provides a detailed breakdown of every item required for a project e.g. cubic meters of concrete, numbers of specific electrical parts, and the like.

Once rates are attached to specific items in a BoQ, a cost estimate for the project can be generated.

The expression ‘Cost Estimate’ has been used herein to indicate when rate values have been applied to a Bill of Quantities (BoQ) to generate a estimate of the costs of the items in the BoQ and thus potentially also an estimate of costs for the whole project.

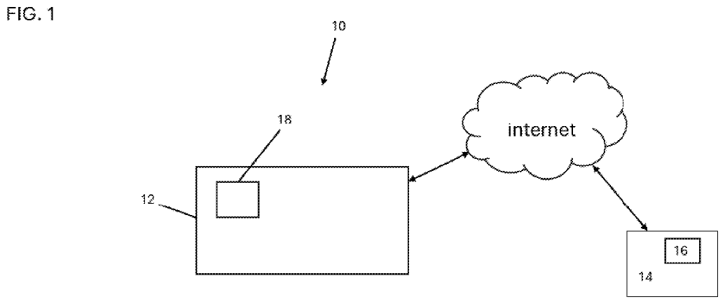

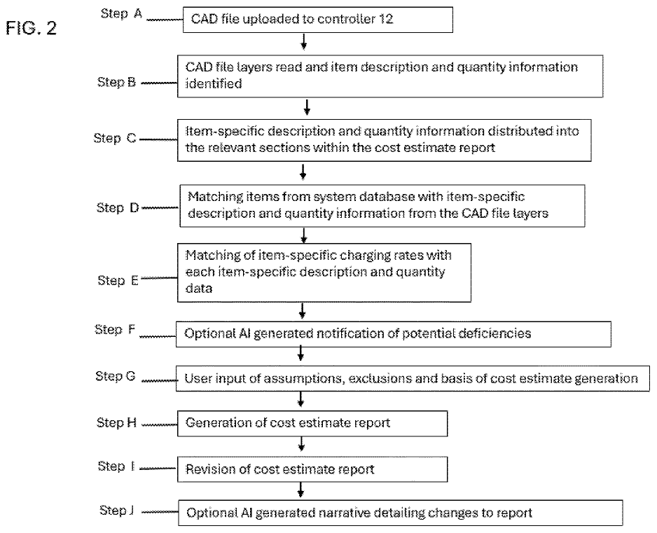

A first embodiment of a system for the preparation of an interactive cost estimate will now be described with reference to FIGS. 1 and 2.

For the purposes of clarity, the following description with respect to the first embodiment makes reference to the AutoCAD computer modelling software. However, it is to be understood that this is for explanatory purposes only and the system per se is not restricted to this specific type of modelling software and is intended to include but not be restricted to Autodesk Civil 3D, AutoCAD, Revit, VectorWorks and Autodesk software packages.

FIG. 1 shows a system 10 comprising a controller 12 with cloud-based user interface or browser. Modem 16 is operable for remote communication with the cloud-based user interface. A user may access the cloud-based user interface via a PC 14 in connection with modem 16 and communicate with controller 12. In FIG. 1, the modem 16 is shown as integral to the PC. However, it is to be appreciated that the modem may be a separate entity in wireless communication with the PC 14. Controller 12 may be further provided with AI capability 18.

In use, a user would communicate with controller 12 via the cloud-based user interface to provide project-specific data for use in the initiation of a cost estimate report. Controller 12 would receive the input data. A user may further upload a AutoCAD .dwg file to the controller 12 via the cloud-based user interface. On receipt of a AutoCAD .dwg file, the controller 12 would read and extract item-specific description and quantity data from respective layers of the AutoCAD .dwg file and populate the cost estimate with the item-specific description and quantity data from the AutoCAD .dwg file layers. This information may then be reviewed and modified by the user, as required, before controller 12 populates the cost estimate with item-specific rate data corresponding to the each item-specific description and quantity data.

The present embodiment involves the use of AutoCAD .dwg drawing files. However, it is to be appreciated that any other suitable/compatible computer aided design file format may be used as an alternative to, or in addition to, AutoCAD .dwg drawing files.

In the present invention, the item-specific rate data may be sourced from a prepopulated rate table containing item-specific rate data. Alternatively, the item-specific rate data may be provided by a user via the user interface. As an alternative to, or in addition to either of the aforementioned sources of item-specific rate data, AI assisted controller software may be used to obtain suggested charge rates for the items in the cost estimate based on multiple parameters including geographical area, inflation rates, knowledge of present and historical cost information and the like and populates the cost estimate with the suggested charge rates. These suggested charge rates may then be reviewed and modified by the user via the user interface, as required, either before the generation of a cost estimate report for the project or to adjust a cost estimate, once generated. The user may also adjust the item-specific description and quantity data manually if changes are required to the cost estimate.

### Initiation of a Cost Estimate Project

As discussed above, a user would typically interact with the system software via a cloud-based platform with a remotely accessible user interface. Using a unique user-specific identifier, a user may enter their preferences relating to the presentation of the final cost estimate, such preferences including, but not restricted to, the name and/or logo, colour branding, preferred font, and the like for the project. These preferences will then be used by the system when generating any documents relating to the project, including the cost estimate report. All preferences can be subsequently modified by the user, if required.

On initiating a cost estimate project, a user will enter data specific to the cost estimate project. Such user specific data includes, but is not restricted to, one or more of the following parameters: project identification (ID) i.e. name and/or number; client information; industrial sector e.g. highways, building, rail, aviation etc; geographical location; base date i.e. date of generation of the cost estimate; project stage e.g. feasibility, concept, detailed; template selection (to ensure correct layout and terminology to suit specific client requirements, industrial sector and/or regulatory requirements); identification of previous estimate being revised (if applicable); identification of specific user generating the cost estimate and their status in the cost estimate process e.g. generator/checker/approver etc; and any other relevant information or notes that are relevant to the cost estimate.

The specific user identification can also include a status identifier that defines the user's permissions within the cost estimate generation process. For example, if the user has the status of ‘generator’, once they have generated a cost estimate, it cannot proceed to the approval stage until checked by a user having a ‘checker’ status who is able to check the cost estimate and progress it to the approval stage for approval by a user with ‘approval status’ and associated permissions to allow the cost estimate to be approved.

It is to be appreciated that the number of users required to generate and progress a cost estimate to the approved stage can be selected on a client basis or on a cost estimate specific basis, in dependence upon operational requirements.

In the event that the cost estimate generation process includes a user with ‘checker’ status, that user will be able to flag up where changes are required. These changes can then be made by the user with ‘generator’ status and provided as tracked changes to be either accepted or rejected by the user with ‘checker’ status.

Once the cost estimate has been initiated, as described above, and the users and their user status identified, the process moves to the next step.

### AutoCAD .dwg File Upload

FIG. 2 is a flow chart of the system at the point of AutoCAD .dwg file upload after initiation of the cost estimate project has been completed.

A user can then upload an AutoCAD .dwg file to the controller 12 that has been prepared by an Engineering team and which provides drawings relating to the construction project (Step A). The system software held on controller 12 will then read the data from respective layers of the AutoCAD .dwg file relating to the item-specific description and quantity data (Step B) and distribute the item-specific description and quantity data into the appropriate sections within the cost estimate report (Step C).

The system software may contain a comprehensive database of pre-loaded items in line with industry standards. The system software will then match pre-loaded items from the database with the item-specific description and quantity data from the AutoCAD .dwg file (Step D) and populate the cost estimate report. However, should an unusual or bespoke item, for example a bespoke bridge or the like, be required that is not present in the database of items, the facility exists for a user to input additional items. Further, a user may modify the quantity of items within a cost estimate report where required.

Once the cost estimate report has been populated with the item-specific description and quantity data from the AutoCAD .dwg file layers, Artificial Intelligence (AI) within the system software may optionally be used to suggest charging rates for each item type and also suggest uplifts based on previously entered location data and inflation rates (Step E). These AI generated rates are then available for review and, if necessary, potential modification by a user, before acceptance and use in the cost estimate. In addition, it may be possible for a user to modify the item description in line with the specific requirements of the project. The AI input will note and learn from any user-generated modifications when providing future AI generated rate suggestions and item descriptions for similar projects.

Alternatively, or in addition, a prepopulated item-specific rate table be used, or the user may input their preferred item-specific rate table. Optionally, AI within the system software may then be employed to adjust the item-specific rates.

AI within the system software may also suggest to the user, any items that may potentially have been missed. For example, if the project is highway related, but the cost estimate does not include traffic management items, AI will flag this deficiency up to the user (Step F). The use can then make the necessary adjustments, if necessary.

Once the quantities and rates have been approved, there will be an opportunity for the user to input any relevant assumptions, exclusions and details of what the cost estimate is based on, how the cost estimate was prepared and any other relevant caveats attached to the cost estimate (Step G)

Once all item quantities and rates have been approved, the final cost estimate report can be generated using a user-selected format, such as word, pdf, excel etc for onward review and approval by the client managing the project (Step H). The cost estimate will remain on the system and available to the user to consult and/or change in the future.

Preferably, the generated cost estimate presents the components in an order conforming to industry standards which allows contractors to immediately identify the section or sections of the cost estimate which relate to their specific part of the project.

### Subsequent Revision

As the design of a project changes over time and user generated changes are made to the items, quantity, rate etc, the system will generate a fresh cost estimate based on the modified inputs (Step I). Previously generated cost-estimate reports will remain on the system for comparative purposes. The revised cost estimate report can then be forwarded for review and approval by the client managing the project. In addition, this may be accompanied by an AI generated narrative detailing the changes that have been made to the previous cost estimate report, together with additional information such as, but not limited to, the date of the previous cost estimate, when the previous cost estimate was generated and provide details of any relative inflation changes (Step J). This will allow a user to readily identify why the cost estimate report has increased/decreased based on any changes to the project design.

Cost estimate reports generated using the system of the present invention may be provided to a client for approval in either document form or via a client-specific log-in to the system via the web browser with read-only permissions. Similarly, a client may be provided with additional privileges to view a cost estimate in progress.

It is to be appreciated that the present invention provides significant advantages over conventional manual measurement of components from a CAD drawing, including increased accuracy of cost estimates, significant saving in man-hours and associated costs. Further, the present invention negates the need for one or more site-visits to obtain more accurate measurements for use in the cost estimate, thereby significantly reducing the carbon emissions and associated carbon footprint generated when compared to the generation of a cost estimate using conventional methods.

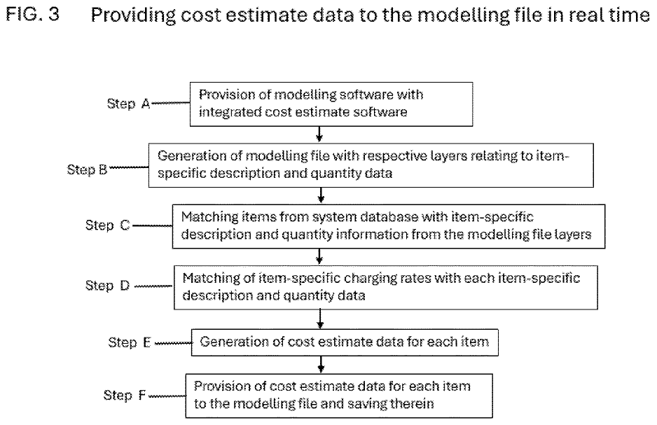

A second embodiment of the system of the present invention is described with reference to the flow chart of FIG. 3.

In the following descriptions, the expression ‘computer modelling file is intended to mean any computer-generated design file holding data relating to a 2D or 3D design. An example of such a file is a computer aided design file (CAD) such as Auto CAD data received from a CAD .dwg file. However, it is to be appreciated that the CAD data may be received from any other suitable, compatible file format, generated by any suitable modelling software such as, but not limited to, Autodesk Civil 3D, AutoCAD, Revit, VectorWorks and Autodesk software packages.

In this second embodiment, the cost estimate software is directly integrated into the computer modelling software e.g. as a plug-in to Autodesk Civil 3D, Auto CAD, Revit, or any other suitable 2D/3D modelling software. Both the cost estimate software and modelling software may be provided locally on a user's PC or, more preferably, may be cloud-based and accessible to anyone with specific access authorisation.

There are two ways to operate the system:

### Real Time Cost Estimate Generation

A user may log into the cost estimate software integrated within the user-selected modelling software, to initiate a new cost estimate project, as previously described.

However, the next step differs from the previous embodiment. Rather than uploading an existing 2D/3D modelling file to the cost estimate software, a user would begin generating such a 2D/3D modelling file within the modelling software.

The user would generate a 2D/3D model in the usual way by generating multiple layers with item-specific description and user-generated dimensions/quantities within the file layer.

However, unlike the previously described embodiment in which the modelling must be completed within the modelling software prior to upload of the file containing the modelling data into the cost estimate software, in this new embodiment, the integrated cost estimate software will generate a cost estimate in real time as the user undertakes the generation of the model within the modelling software.

This is done by the integrated cost estimate software detecting each item-specific description and user-generated dimensions/quantities in the user generated model and matching these to the comprehensive database of pre-loaded items and charging rates withing the cost estimate software, as described above. However, as the cost estimate software and model generating software are integrated, the cost estimate software is updated in real time as changes (e.g. additions, deletions, modifications) are made to the model being generated by the user in the modelling software.

Further, the integrated cost estimate software also tracks changes made by the users. For example, if multiple users have accessed the modelling file and are undertaking work on the same project, the software will log who added features and who deletes features. This is a significant technical advantage that is not provided with conventional modelling software previously mentioned.

The cost estimate software will then read the item-specific data relating to the item-specific description and quantity data and data being entered on the modelling software by the user. The cost estimate software will then match pre-loaded items from the database with the item-specific data, as previously described, and provide this information to the modelling file for visualisation to a user during the generation of the model.

The cost-estimate system operates as previously described, but with the significant technical advantage that the cost estimation is generated in real time, with the user having an awareness of the financial impact of each additional component added to the modelling software on the total cost of the project being modelled.

This system is further described with reference to the flow diagram of FIG. 3.

FIG. 3 is a flow chart of the system at the point of initiation of generation of the 2D/3D model by the modelling software with integrated cost estimate plug-in.

A user can access the modelling software with integrated cost estimate software, for example, in the form of a plug-in (Step A). The software, which may be provided locally, but is preferably cloud based, can then be used by a user to generate respective layers within a modelling file relating to item-specific description and quantity data (Step B). On receipt of item-specific description and quantity data, the integrated cost estimate software will then match items from the cost estimate system database to identify the items (Step C). At this point, sufficient information is available to generate a BoQ based on the item-specific description and quantity data, which may then be provided to the modelling file. In the next step, item-specific charging rates will then be matched with the item-specific description and quantity data in the cost estimate software (Step D) to generate cost estimate data for each item (Step E). The cost estimate data for each item is then provided to the modelling file and saved therein (Step F) for viewing by a user. The cost estimate data is then held as part of the modelling file and, each time the modelling file is opened, this cost estimate data will be available for viewing by a user.

Thus, a user will be provided with real time data relating to the cost of the project as the 2D/3D model is being generated.

Should the user subsequently modify the provided item-specific description and quantity data already provided to the modelling software, the cost estimate software will adjust the cost estimate software in dependence upon the revised item-specific description and quantity data and adjust the cost estimate data accordingly, in real time.

Thus, during the model generation, the user will be provided with real time adjusted cost estimate information, as well as being provided with a final cost estimate at the end of the modelling operation.

Further, where the integrated cost estimate software and modelling software are integrated into a single system, whether provided locally or cloud based, multiple users with access authorisation may access the system and modify the modelling files generated therein. For example, a civil engineer may access a project within the system and generate a modelling file with layers relating to roads and transport based data. A utilities engineer may subsequently (or in tandem) also access the same project within the system, whether in parallel or series, and may further manipulate the modelling file to generate additional layers relating to the associated utilities of the project. When this occurs, the cost estimate software will continue to update the cost estimate in real time for viewing by all authorised users.

Thus, unlike the previously described embodiment of the system of the present invention, the cost estimate software no longer extracts information from the modelling software to independently create a cost estimate for a project in the modelling software. Instead, due to its integration within the modelling software, the cost estimate software now pushes data to the modelling software, where it is retained until there is any modification or deletion of item-specific description and/or quantity data with the project held in the modelling file. At the point of modification or deletion of such data, the integrated cost estimate software will update the cost estimate data accordingly, as previously described.

Further, the real time generation of the cost estimate allows projects to be revised during the modelling process to meet budgetary constraints rather than having the project modelled and subsequently found to be over-budget with a revised modelling operation required in situations where the budget has been exceeded.

Once a user has generated a layer with a selected item-specific description and associated dimensions/quantities, the associated cost estimate data, generated in real time, is retained within the modelling software and accessible to a user on accessing the modelling data file e.g. the AutoCAD file of the like, even in the absence of access to the cost-estimate software plug-in. Thus, the final modelling file may be downloaded containing all the associated real-time generated cost-estimate data.

### Retrospective Cost Estimate Generation

In the first embodiment of the system described above, the modelling software file is uploaded to the cost estimate software and a cost estimate is subsequently generated. However, any changes to the cost estimate would require separate revision of the modelling file and subsequent uploading of the revised modelling file to the cost estimate software for a further cost estimate to be generated in dependence upon the data in the revised modelling file.

In the second embodiment of the system described above, the cost estimate data is generated in real time as the modelling design is created within the modelling file.

However, in this further embodiment, it is possible to open a pre-populated modelling file within the modelling software and have the integrated cost estimate software interact with the pre-populated file, even if it has been generated in the conventional manner in the absence of integrated cost estimate software. Unlike the first embodiment described above, no upload action is required. Simply opening the pre-populated modelling file within the modelling software is sufficient to allow interaction with the integrated cost estimate software. Once a user has selected each layer in the pre-populated modelling file and retrospectively assigned an item from the rate library within the integrated cost estimate software to each element in the prep-populated modelled design, the integrated cost estimate software can automatically generate BoQ data and cost estimate data in real time and provide it to the pre-populated modelling file as described above.

Further, the item-specific description and quantity data within the modelling file may be subsequently revised as described above to obtain real-time modified cost estimate data. Therefore, it is not necessary to generate the modelling file within the integrated modelling and cost estimate software system to access the benefits of real-time cost estimate generation set out above.

1. A system for generating interactive Bill of Quantities (BoQ) data for use in the preparation of interactive cost estimate software, the system comprising:
(iii) a controller; and
(iv) a user interface in communication with the controller,
wherein, on generation of item-specific description and quantity data from computer modelling file, the system is configured to read and extract the item-specific description and quantity data from the computer modelling file; and
wherein the controller is further operable to
(a) generate BoQ data in dependence upon the extracted item-specific description and quantity data; and
(b) supply the BoQ data to the computer modelling file.

2. A system as claimed in claim 1, wherein the system further comprises: a rate database in communication with the controller and populated with item-specific rate data,
wherein, the controller is further operable to identify the item-specific rate data corresponding to the extracted item-specific description and quantity data from each respective data layer; generate cost estimate data in dependence upon the extracted item-specific description and quantity data and the corresponding item-specific rate data; and supply the cost estimate data to the computer modelling file.

3. A system as claimed in claim 1, wherein the controller is configured to supply BoQ data and/or cost estimate data to the computer modelling file in real time.

4. A system as claimed in claim 1, wherein, on revision of the item-specific description and quantity data in the computer modelling file, the controller is further configured to:
(i) extract the revised item-specific description and quantity data from the computer modelling file, generate revised BoQ data in dependence upon the extracted revised item-specific description and quantity data; and
(ii) replace the BoQ data in the computer modelling file with the revised BoQ data.

5. A system as claimed in claim 4, wherein the controller is further configured to generate revised cost estimate data in dependence upon the extracted revised item-specific description and quantity data and the corresponding item-specific rate data; and
replace the cost estimate data in the computer modelling file with the revised cost estimate data.

6. A system as claimed in claim 4, wherein the computer modelling file is generated from modelling software selected from the group comprising: Autodesk Civil 3D, AutoCAD, Revit, VectorWorks and Autodesk software packages.

7. A system as claimed in claim 1, wherein the controller is further configured to receive project-specific data from the user interface and populate the modelling file with the project-specific data.

8. A system as claimed in claim 1, wherein the controller is further configured to adjust the item-specific rate data in dependence upon one or more predetermined factors prior to generation of the cost estimate in dependence upon the item-specific description and quantity data and the item-specific rate data.

9. A system as claimed in claim 6, wherein the factors are selected from the group comprising one or more of cost data, location data, and inflation data.

10. A system as claimed in claim 1, wherein the item-specific rate data may be selectively adjusted in dependence upon user-generated input received by the controller from the user interface.

11. A system as claimed in claim 1, wherein the cost estimate may be selectively adjusted in dependence upon subsequent user generated input received by the controller from the user interface.

12. A method of generation of interactive Bill of Quantities (BoQ) data, the method comprising the steps of:
a. providing a system as claimed in any preceding claim, wherein the system is integrated into or in communication with, modelling software;
b. generating a modelling file within the modelling software or providing a modelling file to the modelling software;
c. extracting item-specific description and quantity data from respective layers of the modelling file;
d. generating BoQ data in dependence upon the item-specific description and quantity data;
e. providing the BoQ data to the modelling file; and
f. saving the BoQ data in the modelling file.

13. A method as claimed in claim 12, further comprising the steps of generating cost estimate data in dependence upon the item-specific description and quality data and the item specific rate data; providing the cost estimate data to the modelling file; and saving the cost estimate data in the modelling file.

14. A method as claimed in claim 12, further comprising the step of adjusting the item-specific rate data in dependence upon one or more predetermined factors selected from the group comprising one or more of cost data, location data, and inflation data.

15. A method as claimed in claim 12, further comprising the step of adjusting the item-specific rate data in dependence upon user-generated input received by the controller from the user interface.

16. A method as claimed in claim 12, further comprising the step of adjusting the cost estimate in dependence upon subsequent user-generated input received by the controller from the user interface.

17. A method as claimed in claim 14, wherein adjusted cost estimate data changes as a consequence of adjustments to the item-specific rate data are provided to the modelling file to replace corresponding previously provided cost-estimate data.

18. A method of generation of an interactive cost estimate as claimed in claim 14, wherein the adjusted cost estimate data is saved to the modelling file.
